(19) United States
(12) Patent Application Publication
(10) Pub. No.: US 2010/0307719 A1
(43) Pub. Date: Dec. 9, 2010

(54) HEAT DISSIPATION DEVICE AND METHOD OF MANUFACTURING THE SAME

(75) Inventors: HONG-CHENG YANG, Shenzhen City (CN); WEI-CHENG NIE, Shenzhen City (CN); CHENG KONG, Shenzhen City (CN)

Correspondence Address: Altis Law Group, Inc.;ATTN: Steven Reiss, 288 SOUTH MAYO AVENUE, CITY OF INDUSTRY, CA, 91789, US

(73) Assignees: FU ZHUN PRECISION INDUSTRY (SHEN ZHEN) CO., LTD., Shenzhen City (CN); FOXCONN TECHNOLOGY CO., LTD., Tu-Cheng (TW)

(21) Appl. No.: 12/542,724

(22) Filed: Aug. 18, 2009

(30) Foreign Application Priority Data
Jun. 4, 2009 (CN) 200910302935.4

(51) Int. Cl. H05K 7/20; F28D 15/04; F28F 7/00; B21D 53/02

(52) U.S. Cl. 165/104.26; 165/185; 165/121; 29/890.03; 165/104.33

(57) ABSTRACT

A heat dissipation device includes a heat sink, a heat-absorbing plate with two slots defined in two lateral sides thereof, a heat pipe connecting the heat-absorbing plate and the heat sink, and a clip having an abutting portion and two locking portions extending from two ends of the abutting portion. The abutting portion presses on the heat pipe, and the locking portions insert through the slots of the heat-absorbing plate and are then bent to lock on the heat-absorbing plate to thereby secure the heat pipe on the heat-absorbing plate.

### BACKGROUND

1. Technical Field

The present disclosure relates generally to a heat dissipation device, and more particularly to a heat dissipation device having a clip for facilitating securing of a heat pipe to a heat-absorbing plate thereof.

2. Description of Related Art

Generally, in order to ensure the normal running of an electronic device, a heat dissipation device is used to dissipate heat generated by the electronic device.

A typical heat dissipation device includes a heat sink, a heat-absorbing plate and a heat pipe with two opposite ends thereof respectively connecting the heat-absorbing plate and the heat sink. The heat-absorbing plate is provided for contacting the electronic device and absorbing heat therefrom. The heat pipe is utilized to transfer heat from the heat-absorbing plate to the heat sink. Usually the end of the heat pipe and the heat-absorbing plate are combined together by soldering for ensuring an intimate contacting therebetween. However, such a fixing mechanism has shortcomings such as high cost and unreliability. There is a risk that the heat pipe and the heat-absorbing plate are connected together without sufficient solder, or even worse that the soldering does not effectively connect the heat pipe and the heat-absorbing plate together, which results in an insufficient contacting between the heat pipe and the heat-absorbing plate, and directly affects a heat dissipation efficiency of the heat dissipation device.

What is need therefore is a heat dissipation device and a method for manufacturing thereof which can overcome the limitation described.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an isometric, assembled view of a heat dissipation device in accordance with an embodiment of the present disclosure.

FIG. 2 is an exploded view of the heat dissipation device of FIG. 1.

FIG. 3 is an inverted, partially enlarged and preassembled view of the heat dissipation device of FIG. 1.

FIG. 4 is an inverted, partially enlarged view of the heat dissipation device of FIG. 1.

### DETAILED DESCRIPTION

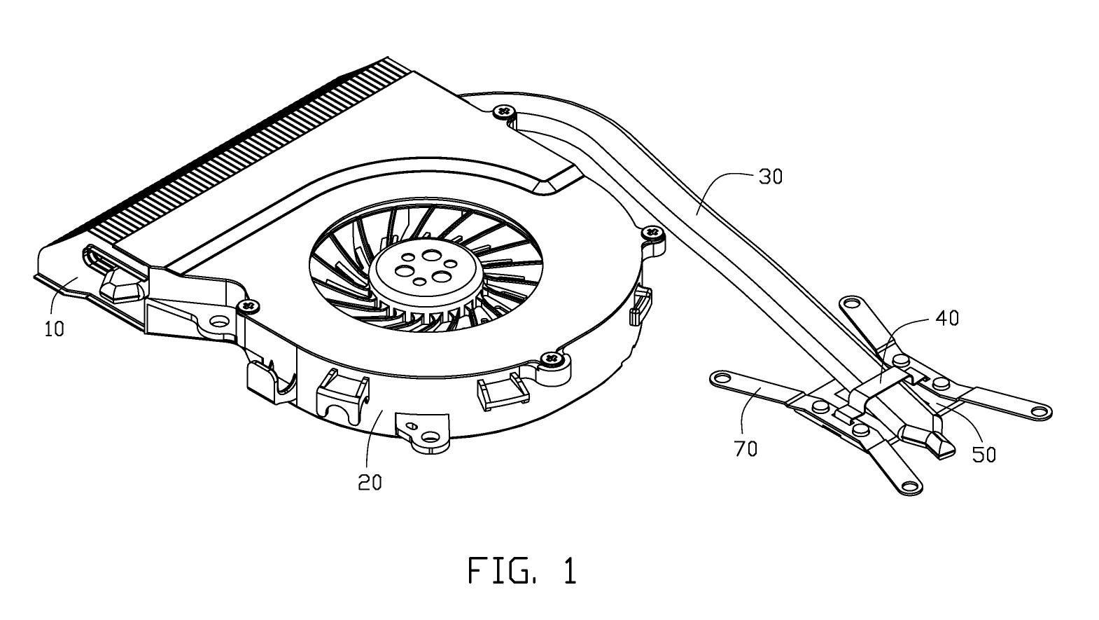

FIGS. 1-3 illustrate a heat dissipation device in accordance with an embodiment of the present disclosure. The heat dissipation device dissipates heat from a heat-generating component 100 such as a CPU mounted on a printed circuit board (not shown). The heat dissipation device comprises a heat sink 10, a centrifugal fan 20 located at a lateral side of the heat sink 10, a heat-absorbing plate 50, a heat pipe 30 connecting the heat sink 10 and the heat-absorbing plate 50, and a clip 40 fixing an end of the heat pipe 30 onto the heat-absorbing plate 50. The heat dissipation device further comprises two locking plates 70 locking the heat-absorbing plate 50 onto the printed circuit board (not shown) so that the heat-absorbing plate can have an intimate contact with the heat-generating component 100.

The heat sink 10 comprises a plurality of parallel fins 12. The fins 12 are vertically arranged such that a plurality of vertical channels 13 are defined therebetween. An opening (not labeled) is defined in the middle of each fin 12. The openings cooperatively define a receiving groove 120 to receive the heat pipe 30.

The centrifugal fan 20 comprises a frame 22 and an impeller 24 rotatably received in the frame 22. A round air inlet 220 is defined in a middle of a top of the frame 22. A straight air outlet (not labeled) is defined at a rear side of the frame 22 corresponding to the channels 13 of the heat sink 10. The air generated by the centrifugal fan 20 flows through the air outlet into the channels 13.

The heat pipe 30 is flattened and comprises a straight evaporating section 32, a straight condensing section 34, and a bending connecting section 36 interconnecting the evaporating section 32 and the condensing section 34. The evaporating section 32 is attached to the heat-absorbing plate 50. The condensing section 34 is received in the groove 120 of the heat sink 10.

The heat-absorbing plate 50 is substantially a rectangular plate and made of material with high heat conductivity such as copper or aluminum. A bottom surface of the heat-absorbing plate 50 is attached to the heat-generating component 10. Two first slots 52 are respectively defined through the heat-absorbing plate 50 and located adjacent to two opposite lateral sides of the heat-absorbing plate 50. The first slots 52 are provided for extension of parts of the clip 40 therethrough. Two columned studs 54 are formed at two ends of each first slot 52. The studs 54 stand on a top surface of the heat-absorbing plate 50. Two rectangular concaves 56 are defined in two lateral sides of the bottom surface of the heat-absorbing plate 50. Each concave 56 is located at an outer lateral side of a corresponding first slot 52 and spaced therefrom.

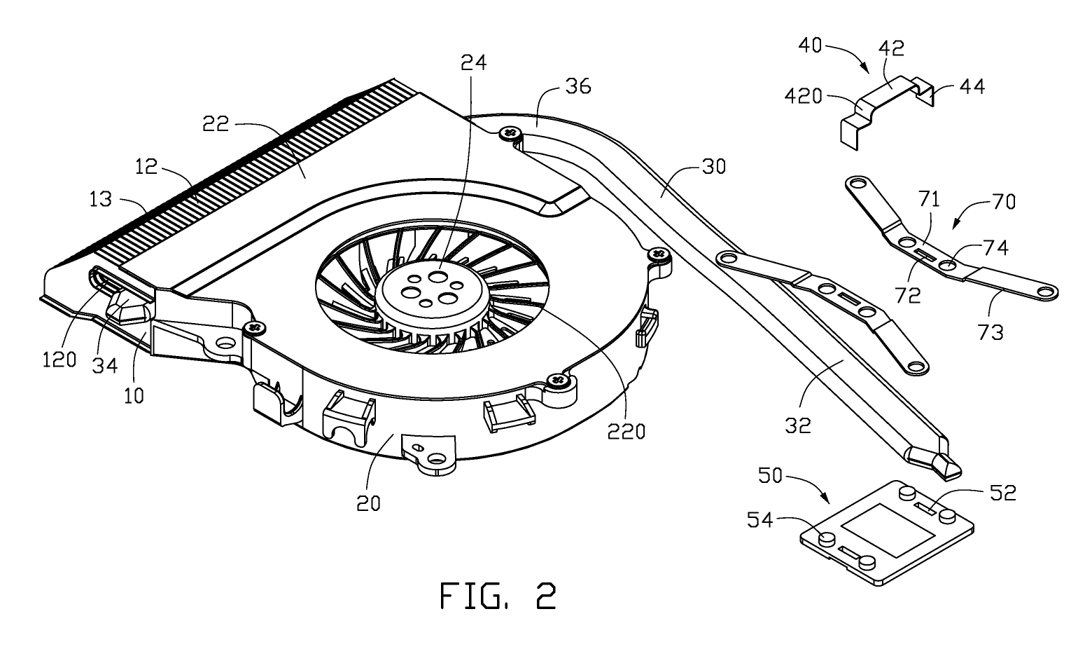

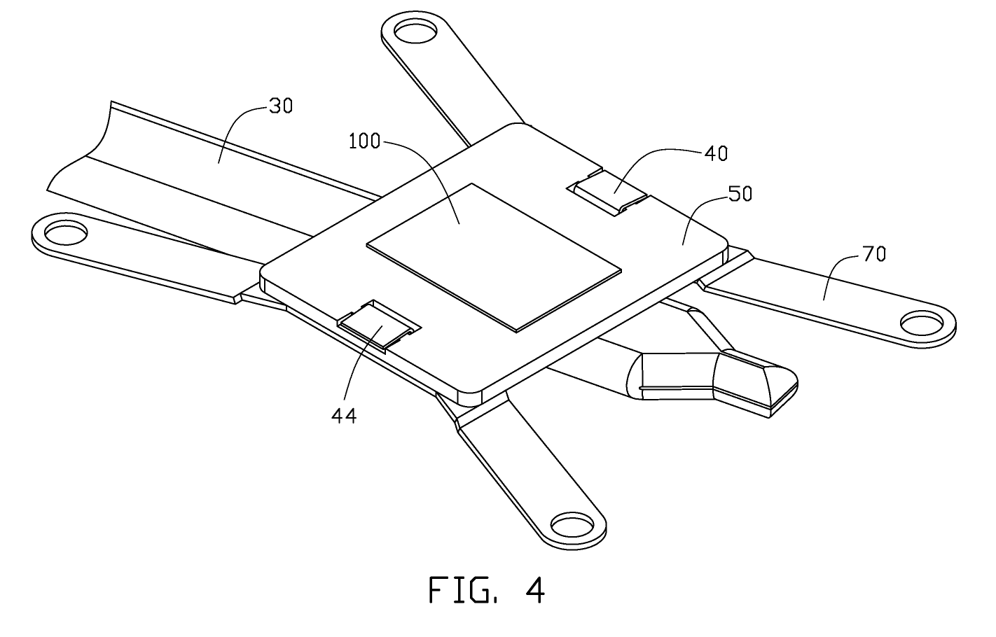

The clip 40 is an integral metal plate and comprises a substantially inverted U shaped abutting portion 42 and two locking portions 44 extending downwardly from two opposite bottom ends of the abutting portion 42. The abutting portion 42 spans the condensing portion 32 of the heat pipe 30 and has two holding arms 420 holding two sides of the condensing portion 32 of the heat pipe 30. The clip 40 shown in FIG. 2 is in an unlocked status and the locking portions 44 thereof each have a substantially inverted L shape. As shown in FIG. 4, after penetrating through the first slots 52 of the heat-absorbing plate 50 and bending outwardly to lock on the heat-absorbing plate 50, the locking portions 44 each are substantially Z shape.

Each locking plate 70 comprises a fixing part 71 fixed on the heat-absorbing plate 50 and two assembly parts 73 extending from two ends of the fixing part 71. A second slot 72 is defined in the middle of the fixing part 71 corresponding to the first slot 52 of the heat-absorbing plate 50. Two holes 74 are defined at two sides of the second slot 72 to correspond to the studs 54 of the heat-absorbing plate 50. The studs 54 can be interferentially engaged in the holes 74 and then riveted to the locking plates 70 to thereby secure the locking plates 70 on the heat-absorbing plate 50. A mounting hole (not labeled) is defined in a free end of each assembly part 73 of each locking plate 70 for a fastener (not labeled) extending therethrough to fix the locking plate 70 onto the printed circuit board.

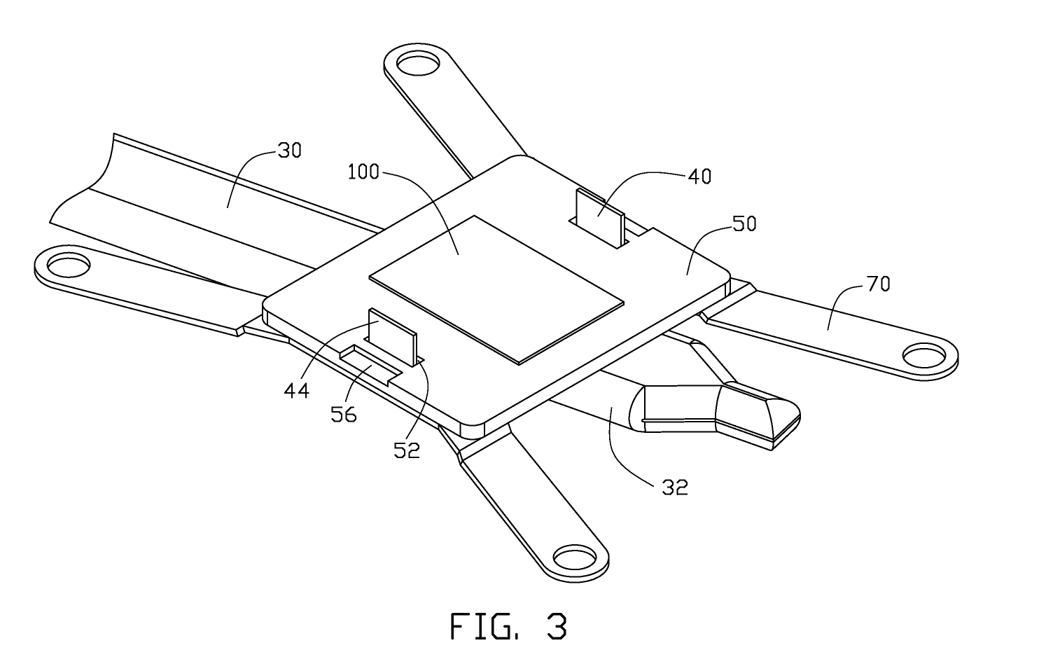

Also referring to FIGS. 3-4, in assembly, the condensing section 34 of the heat pipe 30 is received in the groove 120 of the heat sink 10. The centrifugal fan 20 is located at the side of the heat sink 10, with the air outlet thereof facing to the channels 13 of the heat sink 10. The evaporating section 32 of the heat pipe 30 is thermally attached to the top surface of the heat-absorbing plate 50. The locking plates 70 are fixed on the heat-absorbing plate 50. The locking portions 44 of the clip 40 are inserted into the first and second slots 52, 72 till the abutting portion 42 of the clip 40 abuts against the evaporating section 32 of the heat pipe 30, and upper portions of the locking portions 44 abut against the heat-absorbing plate 50 and the locking plates 70; then, lower portions (i.e., free ends) of the locking portions 44 are bent outwardly and upwardly to make the free ends of the locking portions 44 engage in the concaves 56 defined in the bottom surface of the heat-absorbing plate 50. Thus, the clip 40 locks on the heat-absorbing plate 50, and the heat pipe 30 is intimately attached to the heat-absorbing plate 50 by the clip 40.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A heat dissipation device adapted for dissipating heat generated by a heat-generating component, comprising:
a heat sink;
a heat-absorbing plate with two slots defined in two lateral sides thereof and a bottom surface thereof adapted for contacting the heat-generating component;
a heat pipe connecting the heat-absorbing plate and the heat sink; and
a clip having an abutting portion pressing on the heat pipe and two locking portions extending from two ends of the abutting portion and inserting through the slots of the heat-absorbing plate and bent to lock on the bottom surface of the heat-absorbing plate to secure the heat pipe on the heat-absorbing plate.

2. The heat dissipation device as claimed in claim 1, wherein the abutting portion has an inverted U shape and comprises two holding arms holding two sides of the heat pipe.

3. The heat dissipation device as claimed in claim 1, wherein each of the locking portions has an inverted L shape in an unlocked status, and a Z shape in a locked status.

4. The heat dissipation device as claimed in claim 1, wherein a concave is defined in the bottom surface of the heat-absorbing plate and located at an outer lateral side of a corresponding slot for receiving a corresponding locking portion of the clip.

5. The heat dissipation device as claimed in claim 4, wherein the concave is spaced from the slot.

6. The heat dissipation device as claimed in claim 1, wherein two locking plates are fixed on the heat-absorbing plate adapted for securing the heat-absorbing plate onto a printed circuit board.

7. The heat dissipation device as claimed in claim 6, wherein each of the locking plates defines an additional slot therein corresponding to one of the slots of the heat-absorbing plate for a corresponding locking portion of the clip penetrating therethrough.

8. The heat dissipation device as claimed in claim 1, further comprising a fan located at a side of the heat sink, the fan comprising a frame with an impeller arranged therein and an air outlet defined facing to the heat sink.

9. A method of manufacturing a heat dissipation device, comprising:
providing a heat-absorbing plate with two slots defined therethrough and located at two lateral sides thereof,
providing a heat pipe with one end thereof attached to a top surface of the heat-absorbing plate;
providing a clip having an abutting portion and two locking portions each with an inverted L shape extending from two opposite bottom ends of the abutting portion;
inserting the locking portions of the clip into the slots of the heat-absorbing plate, with the abutting portion of the clip spanning on the heat pipe; and
bending the locking portions and making free ends of the locking portions engage a bottom surface of the heat-absorbing plate to thereby securing the heat pipe onto the heat-absorbing plate.

10. The method as claimed in claim 9, wherein two concaves are defined in the bottom surface of the heat-absorbing plate for receiving the free ends of the locking portions.

11. The method as claimed in claim 10, wherein each of the concaves is spaced from a corresponding one of the slots of the heat-absorbing plate.

12. The method as claimed in claim 9, further comprising providing a heat sink connecting to an opposite end of the heat pipe.

13. The method as claimed in claim 12, further comprising providing a fan located at a side of the heat sink.
